(19) United States
(12) Patent Application Publication
(10) Pub. No.: US 2024/0179837 A1
(43) Pub. Date: May 30, 2024

(54) CONTINUOUS SILICA FIBER REINFORCED COMPOSITES FOR HIGH-FREQUENCY PRINTED CIRCUIT BOARD AND METHODS OF MAKING

(71) Applicant: CORNING INCORPORATED, CORNING, NY (US)

(72) Inventors: Joseph Edward McCarthy, Hornell, NY (US); Geraint Owen, Palo Alto, CA (US); Soumyadyuti Samai, Paris (FR); Meiyu Zhai, South San Fransisco, CA (US)

(21) Appl. No.: 18/519,656

(22) Filed: Nov. 27, 2023

Related U.S. Application Data
(60) Provisional application No. 63/428,771, filed on Nov. 30, 2022.

(51) Int. Cl. H05K 1/03

(52) U.S. Cl. CPC H05K 1/0366; H05K 2201/015; H05K 2201/0158; H05K 2201/0296

(57) ABSTRACT

A printed circuit board (PCB) composite material includes a polymer layer and a fiber layer encapsulated within the polymer layer. The fiber layer includes a first monolayer of continuous silica fibers longitudinally co-aligned in a first direction. Each continuous silica fiber in the first monolayer extends without discontinuity through the polymer layer such that opposed ends of each continuous silica fiber are adjacent to a perimeter of the polymer layer. The PCB composite material has a dielectric loss tangent of less than or equal to about 0.0015 at 15 GHz or higher frequency. A printed circuit board (PCB) includes the PCB composite material and at least one conductive layer disposed on a side of the PCB composite material.

### CROSS-REFERENCE TO RELATED APPLICATIONS

This application claims the benefit of priority under 35 U.S.C. § 119 of U.S. Provisional Application No. 63/428,771, filed Nov. 30, 2022, the content of which is incorporated herein by reference in its entirety.

### FIELD

The disclosure relates generally to the field of composites for printed circuit boards (PCBs) and related applications.

### BACKGROUND

A printed circuit board (PCB) typically comprises an insulating layer between two films of copper cladding. The insulating layer should preferably possess certain properties, such as: good dielectric performance (i.e., low dielectric loss or dissipation factor); dimensional stability at elevated temperature (e.g., at 260° C. for 30 seconds); sufficient mechanical strength and toughness to permit handling during production and post-processing operations (e.g., drilling, cutting, etc.) without damage, burr, or fracture; good adhesion; and fire resistance.

Epoxy/glass composite materials, such as FR4, are currently used for the insulating layers of PCBs due to their good mechanical and thermal properties. Their dielectric losses, though relatively high, are adequate for present applications. However, the dielectric loss performance of epoxy/glass composite materials is inadequate for the GHz performance regime (e.g., >10 GHz). In the near term, dielectric loss tangents of about 0.001 or less may be required for applications operating at several GHz. And over the long term (e.g., for 5G applications), dielectric loss tangents on the order of 0.0001 may be required. Although some commercially available materials have the required dielectric performance characteristics, none combine the required dielectric performance with the dimensional stability and mechanical strength and toughness necessary to withstand handling during PCB production and post-processing operations.

Therefore, a need exists for composite materials that have the mechanical, thermal, and dielectric performance characteristics required for PCB applications at several GHz.

### SUMMARY

A first aspect of the present disclosure includes a composite, comprising: a polymer layer; and a fiber layer encapsulated within the polymer layer, the fiber layer comprising a first monolayer of continuous silica fibers longitudinally co-aligned in a first direction, each continuous silica fiber in the first monolayer extending without discontinuity through the polymer layer such that opposed ends thereof are adjacent to a perimeter of the polymer layer, wherein the composite has a dielectric loss tangent of less than or equal to about 0.0015 at 15 GHz or higher frequency.

A second aspect includes a composite according to the first aspect, wherein the composite has a dielectric loss tangent of less than or equal to about 0.0005 at 15 GHz or higher frequency.

A third aspect includes a composite according to the first aspect or the second aspect, wherein the composite has a dielectric constant of less than or equal to 5.

A fourth aspect includes a composite according to any one of the preceding aspects, wherein the composite has a flexural modulus of about 1 GPa to about 100 GPa or a flexural strength of about 20 MPa to about 175 MPa when measured in the first direction.

A fifth aspect includes a composite according to any one of the preceding aspects, wherein the continuous silica fibers are spaced uniformly in the first monolayer.

A sixth aspect includes a composite according to any one of the preceding aspects, wherein the continuous silica fibers are positioned in contact with one another in the first monolayer.

A seventh aspect includes a composite according to any one of the preceding aspects, wherein the fiber layer comprises a second monolayer of the continuous silica fibers longitudinally co-aligned in a second direction transverse to the first direction, the second monolayer having a planar offset relative to the first monolayer with each continuous silica fiber in the second monolayer extending without discontinuity through the polymer layer such that opposed ends thereof are adjacent to the perimeter of the polymer layer.

An eighth aspect includes a composite according to the seventh aspect, wherein the second direction is transverse to the first direction by an angle in a range of from about 85° to about 95°.

A ninth aspect includes a composite according to the seventh aspect or the eighth aspect, wherein the continuous silica fibers are spaced uniformly in the second monolayer.

A tenth aspect includes a composite according to the seventh aspect or the eighth aspect, wherein the continuous silica fibers are positioned in contact with one another in the second monolayer.

An eleventh aspect includes a composite according to any one of the preceding aspects, wherein the continuous silica fibers are high-purity continuous silica fibers.

A twelfth aspect includes a composite according to any one of the preceding aspects, wherein the continuous silica fibers do not have a coating.

A thirteenth aspect includes a composite according to any one of the preceding aspects, wherein the continuous silica fibers have a round cross section.

A fourteenth aspect includes a composite according to the thirteenth aspect, wherein a diameter of the continuous silica fibers is in a range of from greater than or equal to about 10 μm to less than or equal to about 1 mm.

A fifteenth aspect includes a composite according to any one of the first through twelfth aspects, wherein the continuous silica fibers have a square cross section.

A sixteenth aspect includes a composite according to the fifteenth aspect, wherein a length of one side of the square cross section is in a range of from greater than or equal to about 10 μm to less than or equal to about 1 mm.

A seventeenth aspect includes a composite according to any one of the preceding aspects, wherein the polymer layer has a thickness in a range of from about 20 μm to about 2 mm, and wherein the thickness of the polymer layer is greater than a thickness of the fiber layer.

An eighteenth aspect includes a composite according to any one of the preceding aspects, wherein the polymer layer comprises at least one polymer selected from cyclic olefin polymers or copolymers, polystyrene polymers (PS), polyetheretherketone polymers (PEEK), polyetherimide polymers (PEI), liquid crystal polymers, polypropylene polymers, cyclic olefins, linear olefins, bi-cyclic olefin norbornene and/or ethylene, polyisobutylene, 4-methylpentene, (dimethyl) polyphenyloxide (PPO), or combination thereof.

A nineteenth aspect includes a composite according to any of the first through seventeenth aspects, wherein the polymer layer comprises a polymer composite material, the polymer composite material comprising a cyclic olefin copolymer and a fluoropolymer, wherein the cyclic olefin copolymer and the fluoropolymer are present in a ratio of between 1:99 and 99:1.

A twentieth aspect of the present disclosure includes a printed circuit board (PCB), comprising: a composite according to any one of the preceding aspects, the composite having a first side and a second side opposite the first side; and a first conductive layer disposed on the first side of the composite.

A twenty first aspect includes a PCB according to the twentieth aspect, further comprising a second conductive layer disposed on the second side of the composite.

A twenty second aspect includes a PCB according to the twentieth aspect or the twenty first aspect, wherein a thickness of the PCB is in a range of from about 35 μm to about 2.15 mm.

A twenty third aspect of the present disclosure includes a method of forming a composite for a printed circuit board (PCB), comprising: longitudinally co-aligning continuous silica fibers in a first monolayer on a first polymer layer; covering the continuous silica fibers and the first polymer layer with a second polymer layer; and encapsulating the continuous silica fibers within a unified polymer layer comprising the first polymer layer and the second polymer layer to form the composite, wherein the composite has a dielectric loss tangent of less than or equal to about 0.0015 at 15 GHz or higher frequency.

A twenty fourth aspect includes a method according to the twenty third aspect, wherein longitudinally co-aligning continuous silica fibers in a first monolayer on a first polymer layer comprises: positioning the first polymer layer about the circumference of a spool; and attaching a start of a length of a continuous silica fiber on the first polymer layer and rotating the spool such that the continuous silica fiber forms a rolled continuous silica fiber drawn about the circumference of the spool in the first monolayer on the first polymer layer.

A twenty fifth aspect includes a method according to the twenty fourth aspect, wherein encapsulating the continuous silica fibers within a unified polymer layer comprises: placing the spool with the first polymer layer, the rolled continuous silica fiber, and the second polymer layer in a vacuum oven; evacuating air from the oven; and controlling a temperature within the vacuum oven according to a temperature program to encapsulate the rolled continuous silica fiber within the unified polymer layer.

A twenty sixth aspect includes a method according to the twenty fifth aspect, wherein the air is evacuated from the vacuum oven to a vacuum pressure of at least 0.9 MPa.

A twenty seventh aspect includes a method according to the twenty fifth aspect or the twenty sixth aspect, wherein the temperature program comprises: heating the vacuum oven to a first temperature greater than a glass transition temperature of the first polymer layer and the second polymer layer over a heating period; holding the first temperature in the vacuum oven for a holding period; cooling the vacuum oven to a second temperature lower than the first temperature and greater than room temperature over a cooling period; and removing the spool from the vacuum oven and allowing the unified polymer layer and the encapsulated rolled continuous silica fiber to cool to room temperature.

A twenty eighth aspect includes a method according the twenty seventh aspect, further comprising severing the encapsulated rolled continuous silica fiber at a seam of the unified polymer layer so as to form the encapsulated continuous silica fibers.

A twenty ninth aspect includes a method according to the twenty eighth aspect, wherein the encapsulated continuous silica fibers are spaced uniformly in the first monolayer.

A thirtieth aspect includes a method according to the twenty eighth aspect, wherein the encapsulated continuous silica fibers are positioned in contact with one another in the first monolayer.

### BRIEF DESCRIPTION OF THE DRAWINGS

FIG. 1 is a top view of a composite comprising a polymer layer and a fiber layer with the polymer layer partially transparent to illustrate continuous silica fibers of the fiber layer longitudinally co-aligned within the polymer layer according to embodiments;

FIG. 2A is a cross sectional view of the composite of FIG. 1 along line A-A to illustrate the continuous silica fibers arranged in a monolayer within the polymer layer according to embodiments;

FIG. 2B is a cross sectional view of the composite of FIG. 1 along line A-A to illustrate the continuous silica fibers arranged differently in the monolayer as compared to the continuous silica fibers shown in FIG. 2A according to embodiments;

FIG. 3 is a top view of a composite similar to the composite of FIG. 1 with continuous silica fibers of the fiber layer longitudinally co-aligned in a direction slightly transverse to a length direction of the composite;

FIGS. 4-7 schematically depict aspects of a method for fabricating the composite of FIG. 1 according to embodiments;

FIGS. 8-11 schematically depict aspects of a method for fabricating a composite comprising a polymer layer and a fiber layer comprising two, vertically-offset monolayers of the continuous silica fibers;

FIG. 12 is a schematic representation of a printed circuit board (PCB) with an insulation layer formed from the composite of FIG. 1 and conductive cladding layers disposed on opposite sides of the composite;

FIG. 13 and FIG. 14 are optical cross section images of a composite with the continuous silica fibers that have a round cross section (FIG. 13) and a composite with continuous silica fibers that have a square cross section (FIG. 14);

FIG. 15 is an SEM cross section of a composite comprising a fiber layer with two, vertically-offset monolayers of the continuous silica fibers, such as described with reference to FIGS. 8-11;

FIG. 16 is a digital image of a test configuration for a two-point bend test; and

FIG. 17 presents a digital image of a sample being deflected (left) and a schematic representation of the forces acting on the sample (right) during two-point bend testing using the test configuration of FIG. 16.

### DETAILED DESCRIPTION

For the purposes of promoting an understanding of the principles of the disclosure, reference will now be made to the embodiments illustrated in the drawings and described in the following written specification. It is understood that no limitation to the scope of the disclosure is thereby intended. It is further understood that the present disclosure includes any alterations and modifications to the illustrated embodiments and includes further applications of the principles disclosed herein as would normally occur to one skilled in the art to which this disclosure pertains

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein, unless defined elsewhere in association with specific terms or phrases, are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Directional terms as used herein—for example up, down, right, left, front, back, top, bottom, above, below, and the like—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

The term “permittivity” refers to the ability of a substance, such as the composites of the disclosure, to store electrical energy in the presence of an external electric field. Further, the terms “permittivity” and the “average dielectric constant (Dₖ)” or “dielectric constant” are used interchangeably within this disclosure. The dielectric constant is a quantity measuring the ability of a substance to store electrical energy in an electric field. In the case of lossy materials, permittivity may be expressed as a complex number, known as a “complex permittivity” The real part of the complex number refers to the ability of the material to store electrical energy in the presence of an external electric field. The imaginary part of the complex number quantifies the energy dissipated in the material in the presence of an external electric field. If the material is loss-free, this imaginary term is equal to zero. The terms “average dielectric constant (Dₖ)” and “relative permittivity (εᵣ)” are used interchangeably in the disclosure and are defined as the ratio between the real part of the complex permittivity (absolute permittivity) and permittivity of free space (vacuum permittivity). Materials with an εᵣ>1 are considered to be dielectric materials and poor conductors of electricity.

The terms “loss tangent.” “dielectric loss tangent,” and “dielectric loss” are used interchangeably in this disclosure to refer to the inherent dissipation of electromagnetic energy (e.g., heat) afforded by a particular material, layer, or laminated structure associated with aspects of this disclosure. In general, a dielectric material is more effective in most electronic devices when it has a lower dielectric loss (i.e., portion of energy lost as heat). The loss tangent can be parameterized in terms of either the loss angle δ or the corresponding loss tangent tan δ. The “loss tangent” is expressed as the ratio between the imaginary and real part of the complex permittivity. In general, the average dielectric constant and loss tangent of a material is dependent on the frequency of the external field. Therefore, the dielectric property measured in the kHz range may not represent the dielectric property at microwave frequencies. Further, unless otherwise noted, the “loss tangent” and “average dielectric constant (Dₖ)” attributes of the composites of the disclosure can be measured at frequencies of 10 GHz or greater according to a split post dielectric resonator (SPDR) or an open-cavity resonator configuration according to techniques as understood by those with ordinary skill in the field of the disclosure. The particular method chosen can be selected based on the sample thickness and its lateral dimensions.

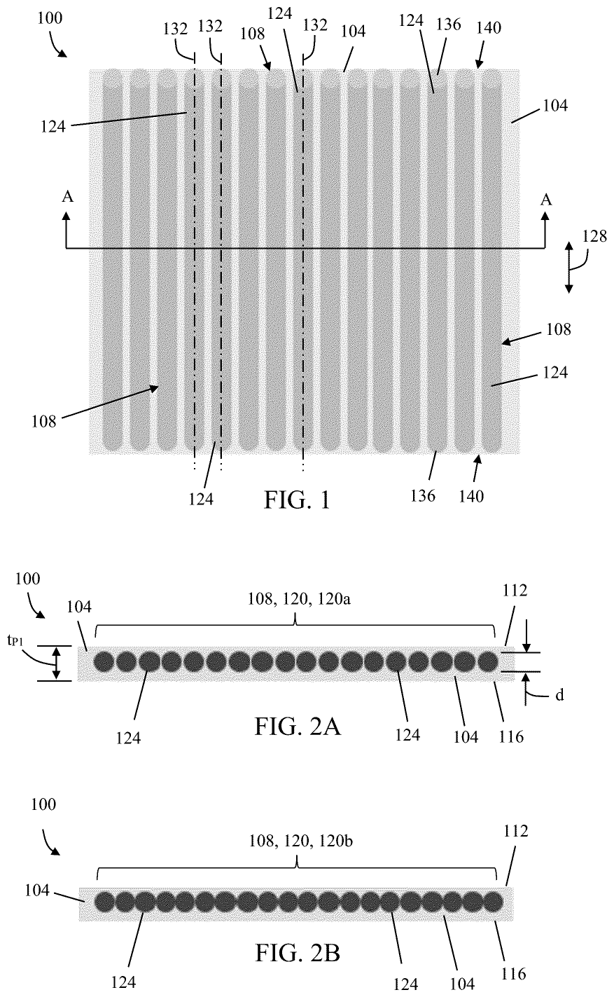

Referring to FIGS. 1, 2A, 2B, and 3, composite materials or composites for printed circuit boards (PCBs) can comprise multiple layers of multiple different materials that possess, collectively or individually, dielectric and mechanical properties that make them suitable in PCB applications at several GHz. In an exemplary embodiment, a composite 100 comprises a polymer layer 104 and a fiber layer 108 disposed within the polymer layer 104. As described in more detail later in this disclosure, the polymer layer 104 can be formed by uniting two or more separate polymer layers, such as a first (or lower) polymer layer 104a and a second (or upper) polymer layer 104b (FIG. 7), with the fiber layer 108 disposed therebetween during fabrication of the composite. As a result of such unification, the fiber layer 108 can be encapsulated within the polymer layer 104. In an exemplary embodiment, the fiber layer 108 is encapsulated centrally within the polymer layer 104 between opposed major surfaces (e.g., a first surface 112 and a second surface) of the composite 100. In embodiments, the fiber layer 108 is positioned proximate a midplane disposed approximately halfway between the opposed major surfaces 112, 116.

In embodiments, a unified polymer layer is formed from the unification of the lower polymer layer and the upper polymer layer, as shown in the cross sectional views of FIG. 2A and FIG. 2B. As used herein, a “unified polymer layer” means that the lower polymer layer (e.g., below the fiber layer 108 in FIG. 2A and FIG. 2B) and the upper polymer layer (e.g., above the fiber layer 108 in FIG. 2A and FIG. 2B) are virtually indistinguishable from one another as a result of the polymer materials used in the composite (e.g., same polymer material) and the methods of uniting the lower and upper polymer layers (e.g., forming an essentially uniform microstructure through the entire polymer layer), which methods are described later in this disclosure. In embodiments, a differentiated polymer layer can be formed from the unification of the lower polymer layer and the upper polymer layer. As used herein, a “differentiated polymer layer” means that the lower polymer layer and the upper polymer layer are distinguishable from one another as a result of the polymer materials used in the composite (e.g., different polymer materials) and the methods of uniting the lower and upper polymer layers (e.g., forming different microstructures through different portions of the polymer layer). In the following description, the polymer layer 104 refers to a unified polymer layer unless indicated otherwise.

In embodiments, as shown in FIG. 7, the first (or lower) polymer layer 104a and the second (or upper) polymer layer 104b each have a thickness t_{PA} and t_{PB}, respectively, of between 10 μm and 1000 μm (1 mm), between 15 μm and 800 μm, between 20 μm and 700 μm, between 30 μm and 650 μm, between 40 μm and 600 μm, between 50 μm and 550 μm, between 60 μm and 500 μm, between 70 μm and 450 μm, between 80 μm and 400 μm, between 90 μm and 350 μm, between 100 μm and 300 μm, or between 150 μm and 250 μm, and also comprising all sub-ranges and sub-values between these range endpoints. In embodiments, the first (or lower) polymer layer 104a and the second (or upper) polymer layer 104b each have a thickness t_{PA} and t_{PB}, respectively, of about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 200 μm, about 250 μm, about 300 μm, about 350 μm, about 400 μm, about 450 μm, about 500 μm, about 550 μm, about 600 μm, about 650 μm, about 700 μm, about 800 μm, about 900 μm, or about 1000 μm (1 mm), or any intermediate value therein.

In embodiments, as shown in FIG. 2A, the polymer layer 104 (e.g., the unified polymer layer and/or the differentiated polymer layer) has a thickness t_{P1} of between 20 μm and 2000 μm (2 mm), between 30 μm and 1600 μm (1.6 mm), between 40 μm and 1400 μm (1.4 mm), between 60 μm and 1300 μm (1.3 mm), between 80 μm and 1200 μm (1.2 mm), between 100 μm and 1100 μm (1.1 mm), between 120 μm and 1000 μm (1 mm), between 140 μm and 900 μm, between 160 μm and 800 μm, between 180 μm and 700 μm, between 200 μm and 600 μm, or between 300 μm and 500 μm, and also comprising all sub-ranges and sub-values between these range endpoints. In embodiments, the polymer layer 104 has a thickness t_{P1} of about 40 μm, about 60 μm, about 80 μm, about 100 μm, about 120 μm, about 140 μm, about 160 μm, about 180 μm, about 200 μm, about 220 μm, about 240 μm, about 260 μm, about 280 μm, about 300 μm, about 400 μm, about 500 μm, about 600 μm, about 700 μm, about 800 μm, about 900 μm, about 1000 μm (1 mm), about 1100 μm (1.1 mm), about 1200 μm (1.2 mm), about 1300 μm (1.3 mm), about 1400 μm (1.4 mm), about 1600 μm (1.6 mm), about 1800 μm (1.8 mm), or about 2000 μm (2 mm), or any intermediate value therein. In embodiments, the thickness t_{P1} of the polymer layer 104 is approximately two times the thickness t_{PA} of the lower polymer layer 104a (FIG. 7) or the thickness t_{PB} of the upper polymer layer 104b (FIG. 7) when the lower and upper polymer layers have the approximately same thickness.

In embodiments, the polymer layer 104 can have a dielectric loss tangent at 10 GHz (or higher frequency) of less than 5×10⁻³, less than 4×10⁻³, less than 3×10⁻³, less than 2×10⁻³, less than 1×10⁻³, less than 9×10⁻⁴, less than 8×10⁻⁴, less than 7×10⁻⁴, less than 6×10⁻⁴, less than 5×10⁻⁴, less than 4×10⁻⁴, less than 3×10⁻⁴, less than 2×10⁻⁴, less than 1×10⁻⁴, less than 9×10⁻⁵, less than 8×10⁻⁵, less than 7×10⁻⁵, less than 6×10⁻⁵, less than 5×10⁻⁵, less than 4×10⁻⁵, less than 3×10⁻⁵, less than 2×10⁻⁵, or less than 1×10⁻⁵, or any range therein. In some embodiments, a low-loss polymer layer has a dielectric loss tangent at 10 GHz (or higher frequency) of about 5×10⁻³, about 4×10⁻³, about 3×10⁻³, about 2×10⁻³, about 1×10⁻³, about 9×10⁻⁴, about 8×10⁻⁴, about 7×10⁻⁴, about 6×10⁻⁴, about 5×10⁻⁴, about 4×10⁻⁴, about 3×10⁻⁴, about 2×10⁻⁴, about 1×10⁻⁴, about 9×10⁻⁵, about 8×10⁻⁵, about 7×10⁻⁵, about 6×10⁻⁵, about 5×10⁻⁵, about 4×10⁻⁵, about 3×10⁻⁵, about 2×10⁻⁵, or about 1×10⁻⁵, or any intermediate value therebetween.

By way of non-limiting example, in embodiments, the polymer layer 104 can comprise, consist essentially of, or consist of any of the following types of materials.

The polymer layer 104 can comprise low-loss polymers or copolymers. In embodiments, the polymer layer(s) comprise one or more polymers selected from (but not limited to) cyclic olefin polymers or copolymers (“COCs”) (e.g., the Topas® COC polymers, APEL®, Zeonor®, Zeonex®, ARTON®, PDM-5061, etc.), polystyrene polymers (PS), polyetheretherketone polymers (PEEK), polyetherimide polymers (PEI), liquid crystal polymers, polypropylene polymers, cyclic olefins, linear olefins, bi-cyclic olefin norbornene, ethylene, polyisobutylene, 4-methylpentene, (dimethyl) polyphenyloxide (PPO), or combinations thereof.

In exemplary embodiments, the polymer layer 104 comprises low-loss polymers or co-polymers selected from the Topas® family, which include cyclic olefin polymers and copolymers comprising cyclic olefin, cyclopentene, and ethylene copolymers. The exact member of the Topas® family chosen depends on desired mechanical and thermal properties required for processing (e.g., during a lamination process) or in the final laminates. In exemplary embodiments, the low-loss polymers are cyclic olefin polymers or copolymers (e.g., Topas® 8700S, Topas® 6013S, or combinations thereof).

In embodiments, the polymer layer 104 has a storage modulus at 260° ° C. of greater than 1×10⁸ Pa, greater than 2×10⁸ Pa, greater than 3×10⁸ Pa, greater than 4×10⁸ Pa, greater than 5×10⁸ Pa, greater than 6×10⁸ Pa, greater than 7×10⁸ Pa, greater than 8×10⁸ Pa, greater than 9×10⁸ Pa, or greater than 1×10⁹ Pa, or any range therebetween. In embodiments, the polymer layer 104 has a storage modulus at 260° C. of about 1×10⁸ Pa, about 2×10⁸ Pa, about 3×10⁸ Pa, about 4×10⁸ Pa, about 5×10⁸ Pa, about 6×10⁸ Pa, about 7×10⁸ Pa, about 8×10⁸ Pa, about 9×10⁸ Pa, or about 1×10⁹ Pa, or any intermediate value therein.

The polymer layer 104 can comprise composite polymer materials (or “polymer composite materials”). In embodiments, the polymer layer 104 comprises a first thermoplastic polymer and a second thermoplastic polymer. The first thermoplastic polymer can comprise a fluoropolymer, such as a fluoropolymer selected from the group comprising: polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoro alkoxy (PFA), or combinations thereof. The second thermoplastic polymer can comprise a low-loss polymer or copolymer, such as a low-loss polymer or copolymer selected from the group comprising: cyclic olefin copolymers, polystyrene polymers, polyetheretherketone polymers, polyetherimide polymers, liquid crystal polymers, polypropylene polymers, cyclic olefins, linear olefins, bi-cyclic olefin norbornene and ethylene, or combinations thereof.

In embodiments, a ratio of the first thermoplastic polymer to the second thermoplastic polymer is in a range of about 1:99 to about 99:1, about 1:90 to about 90:1, about 1:80 to about 80:1, about 1:70 to about 70:1, about 1:60 to about 60:1, about 1:50 to about 50:1, about 1:40 to about 40:1, about 1:30 to about 30:1, about 1:20 to about 20:1, about 1:10 to about 10:1, about 1:5 to about 5:1, about 1:3 to about 3:1, about 1:2 to about 2:1, about 1:1.5 to about 1.5:1, or about 1:1, or any range therebetween. In embodiments, the ratio of the first thermoplastic polymer to the second thermoplastic polymer is about 1:99, about 5:95, about 10:90, about 15:85, about 20:80, about 25:75, about 30:70, about 35:65, about 40:60, about 45:55, about 50:50, about 55:45, about 60:40, about 65:35, about 70:30, about 75:25, about 80:20, about 85:15, about 90:10, about 95:5, or about 99:1, or any ratio therein. In embodiments, the ratio of the first thermoplastic polymer to the second thermoplastic polymer is between 40:60 and 60:40.

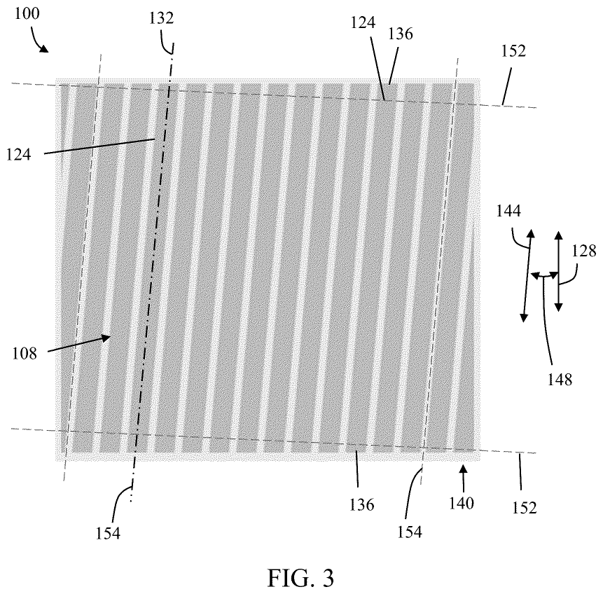

Referring still to FIGS. 1, 2A, 2B, and 3, the fiber layer 108 comprises a first monolayer 120 of continuous silica fibers 124 longitudinally co-aligned in a first direction (arrow 128 in FIG. 1 and FIG. 3). As used herein, a “monolayer” refers to a configuration in which the continuous silica fibers 124 are arranged in a single layer (e.g., adjacent continuous silica fibers arranged longitudinal edge to longitudinal edge) that has a thickness corresponding to a thickness of one continuous silica fiber. In embodiments, the continuous silica fibers 124 are configured to have approximately the same thickness, and a thickness of the fiber layer 108 corresponds to an average thickness of the continuous silica fibers 124 within the (first) monolayer. The longitudinal co-alignment of the continuous silica fibers 124 is illustrated best in FIG. 1, which shows longitudinal axes 132 of the continuous silica fibers 124 oriented in parallel with one another and with the first direction 128. As used herein, a “continuous silica fiber” refers to a continuous silica fiber that extends (in a monolayer) without discontinuity (e.g., no interruption, gaps, breaks, etc. along the length thereof) through the polymer layer 104 such that opposed ends 136 of the continuous silica fiber 124 are adjacent to a perimeter 140 of the polymer layer 104. In embodiments, the continuous silica fibers 124 extend without discontinuity through the polymer layer 104 such that the opposed ends 136 are flush with the perimeter 140 of the polymer layer 104.

Referring now to FIG. 2A and FIG. 2B, the continuous silica fibers 124 are positioned uniformly (e.g., uniform or constant pitch) relative to one another within the first monolayer 120. In embodiments, the continuous silica fibers 124 are spaced uniformly (e.g., adjacent continuous silica fibers have a uniform gap or spacing therebetween) in a first configuration 120a (FIG. 2A) of the first monolayer 120. In embodiments, the continuous silica fibers 124 are positioned in contact with one another (e.g., adjacent continuous silica fibers have longitudinal edge to longitudinal edge contact therebetween) in a second configuration 120b (FIG. 2B) of the first monolayer 120. Without being bound by theory, the continuous silica fibers 124 having a uniform or constant pitch within the first monolayer 120 may be important to reduce and/or avoid of phase or timing errors related to signal transmission in conductive lines operating in the GHz frequency regime.

Referring again to FIG. 1, the first direction 128 along which the continuous silica fibers 124 within the first monolayer 120 are longitudinally co-aligned generally corresponds to a lengthwise direction of the composite 100 (e.g., a direction up and down relative to the view of FIG. 1 and corresponding to the first direction 128). Referring now to FIG. 3, the continuous silica fibers 124 can be longitudinally co-aligned within the first monolayer 120 in a skew direction (arrow 144 in FIG. 3) slightly transverse to the lengthwise direction of the composite 100 depending on the methods used to fabricate the composite, as described later in this disclosure. For example, in embodiments, the skew direction 144 forms a nonzero angle 148 with the first direction 128. In embodiments, it may be preferable for the longitudinal co-alignment of the continuous silica fibers 124 not to have a skew angle 148 relative to the lengthwise direction of the composite 100. In such embodiments, the composite 100 having the skew angle 148 can be sectioned in such away so as to provide a modified composite that does not have the skew angle. For example, the composite 100 having the skew angle 148 can be cut or sectioned along a first pair of section planes 152 oriented perpendicular to the longitudinal axes 132 of the continuous silica fibers 124 and along a second pair of section planes 154 oriented parallel to the longitudinal axes 132 of the continuous silica fibers 124 to provide the modified composite that does not have the skew angle.

In embodiments, the continuous silica fibers 124 can have a round cross section with a diameter d, as shown in FIG. 2A and FIG. 2B. In such embodiments, the continuous silica fibers 124 each have a diameter d (e.g., the thickness) of between 10 μm and 1000 μm (1 mm), between 15 μm and 800 μm, between 20 μm and 700 μm, between 30 μm and 650 μm, between 40 μm and 600 μm, between 50 μm and 550 μm, between 60 μm and 500 μm, between 70 μm and 450 μm, between 80 μm and 400 μm, between 90 μm and 350 μm, between 100 μm and 300 μm, or between 150 μm and 250 μm, and also comprising all sub-ranges and sub-values between these range endpoints. In embodiments, the continuous silica fibers 124 each have a diameter d (e.g., the thickness) of about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 200 μm, about 250 μm, about 300 μm, about 350 μm, about 400 μm, about 450 μm, about 500 μm, about 550 μm, about 600 μm, about 650 μm, about 700 μm, about 800 μm, about 900 μm, or about 1000 μm (1 mm), or any intermediate value therein.

In embodiments, the continuous silica fibers 124 can have a square cross section with the sides thereof each having a length l, as shown in the optical cross sectional image of FIG. 14. In such embodiments, the continuous silica fibers 124 each have a length l (e.g., the thickness) of between 10 μm and 1000 μm (1 mm), between 15 μm and 800 μm, between 20 μm and 700 μm, between 30 μm and 650 μm, between 40 μm and 600 μm, between 50 μm and 550 μm, between 60 μm and 500 μm, between 70 μm and 450 μm, between 80 μm and 400 μm, between 90 μm and 350 μm, between 100 μm and 300 μm, or between 150 μm and 250 μm, and also comprising all sub-ranges and sub-values between these range endpoints. In embodiments, the continuous silica fibers 124 each have a length l (e.g., the thickness) of about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 200 μm, about 250 μm, about 300 μm, about 350 μm, about 400 μm, about 450 μm, about 500 μm, about 550 μm, about 600 μm, about 650 μm, about 700 μm, about 800 μm, about 900 μm, or about 1000 μm (1 mm), or any intermediate value therein.

In embodiments, the thickness t_{P1} of the polymer layer 104 (e.g., the unified polymer layer and/or the differentiated polymer layer) is greater than the thickness of the fiber layer 108. In other words, the thickness t_{P1} of the polymer layer 104 is greater than the diameter d of the continuous silica fibers 124 having the round cross section. Similarly, the thickness t_{P1} of the polymer layer 104 is greater than the length l of the continuous silica fibers 124 having the square cross section. Such a relationship between the thickness t_{P1} of the polymer layer 104 and the thickness of the fiber layer 108 can help ensure the continuous silica fibers 124 are fully encapsulated by the polymer layer 104 during fabrication of the composite 100.

In embodiments, the continuous silica fibers 124 are formed from high-purity (fused) silica. As used herein, “high-purity silica” is silica that contains less than 1 ppb of water (OH) measured using Fourier-transform infrared spectroscopy (FTIR) and less than 1 ppb of alkali and metal impurities measured using inductively coupled plasma mass spectrometry (ICP-MS). In an exemplary embodiment, the continuous silica fibers 124 are uncoated (e.g., the continuous silica fibers 124 do not have any protecting coating applied thereon before, during, or after drawing of the fibers). The uncoated, high-purity silica fibers are available from Corning Incorporated. In embodiments, the continuous silica fibers 124 contain silica at a concentration of more than 95 wt. %, more than 96 wt. %, more than 97 wt. %, more than 98 wt. %, more than 99 wt. %, more than 99.9 wt. %, more than 99.99 wt. %, or even more than 99.999 wt. %.

In embodiments, the continuous silica fibers 124 have a dielectric loss tangent at 10 GHz (or higher frequency) of less than 6×10⁻³, less than 5×10⁻³, less than 4×10⁻³, less than 3×10⁻³, less than 2×10⁻³, less than 1×10⁻³, less than 9×10⁻⁴, less than 8×10⁻⁴, less than 7×10⁻⁴, less than 6×10⁻⁴, less than 5×10⁻⁴, less than 4×10⁻⁴, less than 3×10⁻⁴, less than 2×10⁻⁴, less than 1×10⁻⁴, less than 9×10⁻⁵, less than 8×10⁻⁵, less than 7×10⁻⁵, less than 6×10⁻⁵, less than 5×10⁻⁵, less than 4×10⁻⁵, less than 3×10⁻⁵, less than 2×10⁻⁵, or less than 1×10⁻⁵, or any range therebetween. In embodiments, the continuous silica fibers 124 have a dielectric loss tangent at 10 GHz (or higher frequency) of about 6×10⁻³, about 5×10⁻³, about 4×10⁻³, about 3×10⁻³, about 2×10⁻³, about 1×10⁻³, about 9×10⁻⁴, about 8×10⁻⁴, about 7×10⁻⁴, about 6×10⁻⁴, about 5×10⁻⁴, about 4×10⁻⁴, about 3×10⁻⁴, about 2×10⁻⁴, about 1×10⁻⁴, about 9×10⁻⁵, about 8×10⁻⁵, about 7×10⁻⁵, about 6×10⁻⁵, about 5×10⁻⁵, about 4×10⁻⁵, about 3×10⁻⁵, about 2×10⁻⁵, or about 1×10⁻⁵, or any intermediate value therein.

In embodiments, the continuous silica fibers 124 have a dielectric constant of equal to or less than 10.0, equal to or less than 9.5, equal to or less than 9.0, equal to or less than 8.5, equal to or less than 8.0, equal to or less than 7.5, equal to or less than 7.0, equal to or less than 6.5, equal to or less than 6.0, equal to or less than 5.5, equal to or less than 5.0, equal to or less than 4.5, equal to or less than 4.0, equal to or less than 3.5, equal to or less than 3.0, equal to or less than 2.5, equal to or less than 2.0, equal to or less than 1.5, or equal to or less than 1.0, or any range therein. In embodiments, the continuous silica fibers 124 have a dielectric constant of about 10.0, 9.9, 9.8, 9.7, 9.6, 9.5, 9.4, 9.3, 9.2, 9.1, 9.0, 8.9, 8.8, 8.7, 8.6, 8.5, 8.4, 8.3, 8.2, 8.1, 8.0, 7.9, 7.8, 7.7, 7.6, 7.5, 7.4, 7.3, 7.2, 7.1, 7.0, 6.9, 6.8, 6.7, 6.6, 6.5, 6.4, 6.3, 6.2, 6.1, 6.0, 5.9, 5.8, 5.7, 5.6, 5.5, 5.4, 5.3, 5.2, 5.1, 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.7, 2.6, 2.5, 2.4, 2.3, 2.2, 2.1, 2.0, 1.9, 1.8, 1.7, 1.6, 1.5, 1.4, 1.3, 1.2, or 1.0, or any value therebetween.

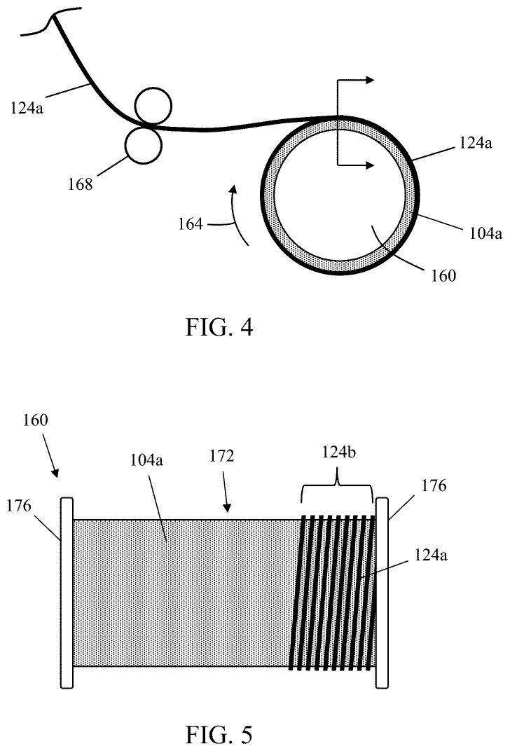

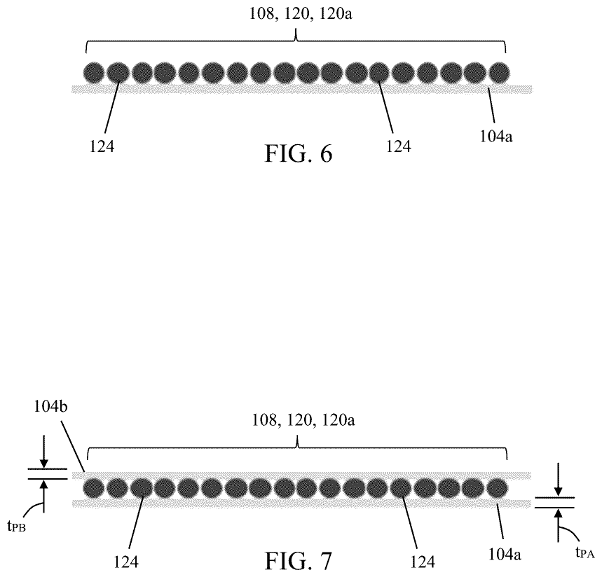

Referring now to FIGS. 4-7, aspects of an exemplary method for forming a composite for a printed circuit board (PCB), such as the composite 100, are shown and described. The method initially comprises longitudinally co-aligning continuous silica fibers 124 of a fiber layer 108 within a first monolayer 120 on a first polymer layer 104a, as shown in FIG. 6 (see also FIG. 1 and FIG. 3). Next, the method includes covering the continuous silica fibers 124 and the first polymer layer 104a with a second polymer layer 104b, as shown in FIG. 7. Next, the method includes encapsulating the continuous silica fibers 124 within a unified polymer layer 104 comprising the first polymer layer 104a and the second polymer layer 104b to form the composite 100 shown in FIGS. 1, 2A, 2B, and 3.

In embodiments, the step of longitudinally co-aligning continuous silica fibers 124 in a first monolayer 120 on a first polymer layer 104a comprises positioning the first polymer layer 104a about the circumference of a spool 160, as shown in FIG. 4 and FIG. 5. The spool 160 is formed from a material configured withstand the temperatures at which the polymer layers 104a, 104b and the fiber layer 108 are laminated to encapsulate the continuous silica fibers 124 within the unified polymer layer 104. In an exemplary embodiment, the spool 160 is formed from a glass-based material. An intermediary material (not shown) can be placed between the circumference of the spool 160 and the first polymer layer 104a to prevent the first polymer layer 104a from sticking to the spool 160.

In embodiments, the step of longitudinally co-aligning continuous silica fibers 124 in a first monolayer 120 on a first polymer layer 104a further comprises attaching a start of a length of a continuous silica fiber 124a (FIG. 4 and FIG. 5) on the first polymer layer 104a and rotating the spool 160 (e.g., rotation direction indicated by arrow 164 in FIG. 4) such that the continuous silica fiber 104a forms a rolled continuous silica fiber 124b (FIG. 5) drawn about the circumference of the spool 160 in the first monolayer 120 on the first polymer layer 104a. In embodiments, the traverse pitch for winding the continuous silica fiber 104a about the circumference of the spool is configured to position the respective windings uniformly relative to one another within the first monolayer 120. In embodiments, the traverse pitch is configured to wind the continuous silica fiber 104a with one fiber next to the previous fiber without any gaps therebetween such that the respective windings are in contact with one another (e.g., FIG. 2B). In embodiments, the traverse pitch can be configured to wind the continuous silica fiber 104a with one fiber spaced uniformly relative to the previous fiber within the first monolayer 120 (e.g., FIG. 2A).

The continuous silica fiber 124a fed to the spool 160 can be drawn from a draw tower according to known techniques. However, in an exemplary embodiment, no coating (e.g., no protective coating) is applied to the continuous silica fiber 124a on the draw. The protective coating is omitted in the exemplary embodiment because such protective coatings may increase the dielectric loss tangent of the continuous silica fibers 124, which is contrary to the intended technical effect of the composites disclosed herein (e.g., to reduce the dielectric loss tangent at higher frequencies). To minimize the risk of the continuous silica fiber 124a breaking during the forming of the composite, tractor and pulleys 168 used to feed, handle, and/or manipulate the continuous silica fiber 124a are kept wet with ethyl alcohol. Enough of the continuous silica fiber 124a is drawn to cover a flat portion 172 of the spool 160 (e.g., the circumference of the spool 160 between end walls 176 thereof). Once the rolled continuous silica fiber 124b completely covers the flat portion of the spool 160, the second polymer layer 104b is positioned about the circumference of the spool 160 to cover the rolled continuous silica fiber 124b and the first polymer layer 104a, which results in the configuration shown in FIG. 7.

In embodiments, the step of encapsulating the continuous silica fibers within a unified polymer layer comprises placing the spool 160 with the first polymer layer 104a, the rolled continuous silica fiber 124b, and the second polymer layer 104b in a vacuum oven (not shown), evacuating air from the oven, and controlling a temperature within the vacuum oven according to a temperature program to encapsulate the rolled continuous silica fiber 124b within the unified polymer layer 104. In embodiments, the air is evacuated from the vacuum oven to a vacuum pressure of at least 0.9 MPa.

In embodiments, the temperature program comprises heating the vacuum oven to a first temperature. In embodiments, the first temperature is greater than a glass transition temperature Tg of the first and second polymer layers 104a, 104b. In an exemplary embodiment, the first temperature is in a range of from about 150° C. to about 250° C., or from about 160° ° C. to about 240° C., or from about 170° C. to about 230° C., or from about 180° C. to about 220° C., or from about 190° C. to about 210° C., or higher or lower temperature ranges than indicated here. The vacuum oven can be brought to the first temperature over a heating period, such as 20 minutes, 30 minutes, 40 minutes, 50 minutes, 60 minutes, or more or less time than the heating periods indicated here.

In embodiments, after the vacuum oven reaches the first temperature, the temperature program comprises holding the vacuum oven at the first temperature for a holding period, such as 10 minutes, 15 minutes, 20 minutes, 25 minutes, 30 minutes, 35 minutes, 40 minutes, or 50 minutes, or 60 minutes, or more or less time than the holding periods indicated here. In embodiments, after the first temperature is held for the holding period, the temperature program comprises cooling the vacuum oven to a second temperature that is lower than the first temperature and higher than room temperature (e.g., higher than about 20° C.). In embodiments, the vacuum oven is cooled from the first temperature to the second temperature over a cooling period, such as 2 minutes, 4 minutes, 5 minutes, 6 minutes, 7 minutes, 8 minutes, 9 minutes, 10 minute or more or less time than the cooling periods indicated here. In embodiments, after the vacuum oven is cooled to the second temperature, the method comprises removing the spool 160 from the vacuum oven and allowing the unified polymer layer 104 and the encapsulated rolled continuous silica fiber 124b to cool to room temperature.

In embodiments, the method further comprises severing (e.g., cutting) the encapsulated rolled continuous silica fiber 124b at a seam of the unified polymer layer 104 so as to form the composite 100 with the encapsulated continuous silica fibers 124. It should be appreciated that the severing of the rolled continuous silica fiber 124b results in the severed continuous silica fibers 124 having a longitudinal co-alignment in the skew direction 144, as illustrated in FIG. 3, since the traverse pitch used to wind the continuous silica fiber 124a about the circumference of the spool 160 induces such a skew in fibers, as shown in FIG. 5.

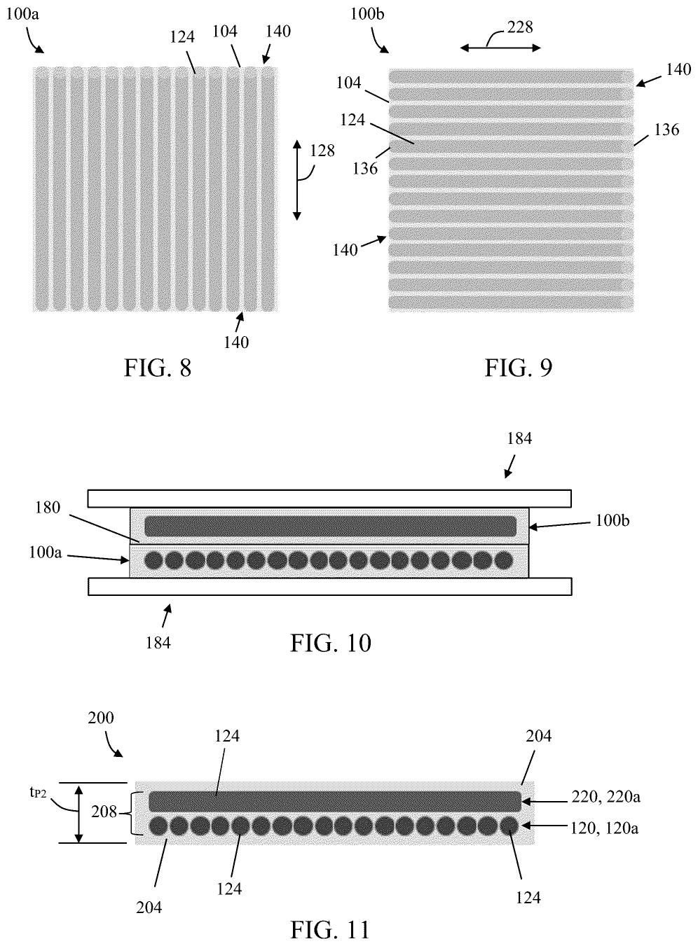

Referring now to FIGS. 8-11, a composite 200 according to FIG. 11 (hereinafter “double composite”) can be fabricated by combining two of the composites 100 according to FIGS. 1-7 (hereinafter “single composite”). The first single composite 100a shown in FIG. 8 and the second single composite 100b shown in FIG. 9 are essentially identical except that the second single composite 100b is rotated approximately 90° relative to an axis oriented perpendicular to the view of FIG. 8 and FIG. 9. In an exemplary embodiment, a major bottom surface of the polymer layer 104 of the second single composite 100b is positioned against a major top surface of the polymer layer 104 of the first single composite 100a at an interface 180 therebetween. In embodiments, the first and second single composites 100a, 100b are positioned relative to one another in a mold, such as a stainless steel mold.

Next, the first and second single composites 100a, 100b are bonded together under vacuum pressure in a hot press 180 (e.g., schematically depicted in FIG. 10) configured to apply controlled pressure and temperature to the first and second single composites 100a, 100b. As a result of such controlled pressure and temperature, the major surfaces of the first and second single composites 100a, 100b at the interface 180 bond together so as to form the double composite 200 shown in FIG. 11.

The double composite 200 of FIG. 11 is similar to the single composite 100 of FIG. 1 except with regard to a thickness of the polymer layer and the contents of the fiber layer. In particular, the polymer layer 204 of the double composite 200 of FIG. 11 has a thickness t_{P2} that is approximately the sum of the thicknesses tri of the polymer layers 104 of the first and second single composites 100a, 100b, as shown in FIG. 8 and FIG. 9 in connection with FIG. 2. The fiber layer 208 of the double composite 200 comprises the first monolayer 120 of the continuous silica fibers 124 and a second monolayer 220 of the continuous silica fibers 124 longitudinally co-aligned in a second direction 228 (FIG. 9) transverse to the first direction 128 (FIG. 8). In embodiments, the second direction 228 is transverse to the first direction 128 by an angle in a range of from about 85° to about 95°. As shown in FIG. 11, the second monolayer 220 has a (vertical) planar offset relative to the first monolayer 120 (e.g., the second monolayer 220 is positioned above or below the first monolayer 120). With reference to FIG. 11 in connection with FIG. 9, each continuous silica fiber 124 in the second monolayer 220 extends without discontinuity through the polymer layer 204 such that opposed ends 136 thereof are adjacent to the perimeter 140 of the polymer layer 204.

As shown in FIG. 11, the continuous silica fibers 124 are spaced uniformly (e.g., adjacent continuous silica fibers have a uniform gap or spacing therebetween) in the first configuration 120a of the first monolayer 120. As shown in FIG. 11 in connection with FIG. 9, the continuous silica fibers 124 are also spaced uniformly in a first configuration 220a of the second monolayer 220. Alternatively, the continuous silica fibers 124 can be positioned in contact with one another (e.g., adjacent continuous silica fibers have longitudinal edge to longitudinal edge contact therebetween) in a second configuration of the second monolayer 220, similar to the continuous silica fibers 124 shown in the second configuration 120b of the first monolayer 120 depicted in FIG. 2B.

The composites 100, 200 describe herein have dielectric and mechanical properties that make them suitable for use in PCB applications at several GHz. In embodiments, the composites 100, 200 have a dielectric loss tangent suitable for use in high-frequency (e.g., 10 GHz or higher frequency) applications. In embodiments, the composites 100, 200 have a dielectric loss tangent at 10 GHz (or higher frequency) of less than 5×10⁻³, less than 4×10⁻³, less than 3×10⁻³, less than 2×10⁻³, less than 1.5×10⁻³, less than 1×10⁻³, less than 9×10⁻⁴, less than 8×10⁻⁴, less than 7×10⁻⁴, less than 6×10⁻⁴, less than 5×10⁻⁴, less than 4×10⁻⁴, less than 3×10⁻⁴, less than 2×10⁻⁴, or less than 1×10⁻⁴, less than 9×10⁻⁵, less than 8×10⁻⁵, less than 7×10⁻⁵, less than 6×10⁻⁵, less than 5×10⁻⁵, less than 4×10⁻⁵, less than 3×10⁻⁵, less than 2×10⁻⁵, or less than 1×10⁻⁵. In embodiments, the composites 100, 200 have a dielectric loss tangent at 10 GHz (or higher frequency) of about 1×10⁻⁵, about 2×10⁻⁵, about 3×10⁻⁵, about 4×10⁻⁵, about 5×10⁻⁵, about 6×10⁻⁵, about 7×10⁻⁵, about 8×10⁻⁵, about 9×10⁻⁵, about 1×10⁻⁴, about 2×10⁻⁴, about 3×10⁻⁴, about 4×10⁻⁴, about 5×10⁻⁴, about 6×10⁻⁴, about 7×10⁻⁴, about 8×10⁻⁴, about 9×10⁻⁴, about 1×10⁻³, about 1.5×10⁻³, about 2×10⁻³, about 3×10⁻³, about 4×10⁻³, or about 5×10⁻³.

In embodiments, the composites 100, 200 have a dielectric constant of less than 15.0, less than 14.0, less than 13.0, less than 12.0, less than 11.0, less than 10.0, less than 9.5, less than 9.0, less than 8.5, less than 8.0, less than 7.5, less than 7.0, less than 6.5, less than 6, less than 5.5, less than 5, less than 4.5, less than 4.0, less than 3.5, less than 3, less than 2.5, or less than 2, at a measurement frequency of, e.g., 10 GHz (or higher frequency). In embodiments, the composites 100, 200 have a dielectric constant of about 10.0, 9.9, 9.8, 9.7, 9.6, 9.5, 9.4, 9.3, 9.2, 9.1, 9.0, 8.9, 8.8, 8.7, 8.6, 8.5, 8.4, 8.3, 8.2, 8.1, 8.0, 7.9, 7.8, 7.7, 7.6, 7.5, 7.4, 7.3, 7.2, 7.1, 7.0, 6.9, 6.8, 6.7, 6.6, 6.5, 6.4, 6.3, 6.2, 6.1, 6.0, 5.9, 5.8, 5.7, 5.6, 5.5, 5.4, 5.3, 5.2, 5.1, 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.75, 2.7, 2.6, 2.5, 2.4, 2.3, 2.2, 2.1, 2.0, 1.9, 1.8, 1.7, 1.6, 1.5, 1.4, 1.3, 1.2, or 1.0, or any value therebetween. In an exemplary embodiment, the composites 100, 200 have a dielectric constant of less than 3.5 at a measurement frequency of 10 GHz (or higher frequency).

In embodiments, the composites 100, 200 have a flexural modulus of about 1 GPa to about 100 GPa, about 2 GPa to about 95 GPa, about 3 GPa to about 90 GPa, about 4 GPa to about 85 GPa, about 5 GPa to about 80 GPa, about 6 GPa to about 75 GPa, about 2.5 GPa to about 70 GPa, about 7 GPa to about 70 GPa, about 8 GPa to about 65 GPa, about 9 GPa to about 65 GPa, or about 10 GPa to about 65 GPa. In embodiments, the composites 100, 200 have a flexural modulus of about 1 GPa, 2 GPa, 3 GPa, 4 GPa, 5 GPa, 6 GPa, 7 GPa, 8, GPa, 9 GPa, 10 GPa, 11 GPa, 12 GPa, 13 GPa, 14 GPa, 15 GPa, 20 GPa, 25 GPa, 30 GPa, 35 GPa, 40 GPa, 45 GPa, 50 GPa, 55 GPa, 60 GPa, 65 GPa, 70 GPa, 75 GPa, 80 GPa, 85 GPa, 90 GPa, 95 GPa, or 100 GPa, or any value therebetween.

In embodiments, the composites 100, 200 have a flexural strength of about 20 MPa to about 300 MPa, about 25 MPa to about 275 MPa, about 30 MPa to about 250 MPa, about 35 MPa to about 225 MPa, about 40 MPa to about 200 MPa, about 45 MPa to about 175 MPa, or about 50 MPa to about 150 MPa, or any range therein. In embodiments, the composites 100, 200 have a flexural strength of about 20 MPa, about 25 MPa, about 30 MPa, about 35 MPa, about 40 MPa, about 45 MPa, about 50 MPa, about 55 MPa, about 60 MPa, about 65 MPa, about 70 MPa, about 75 MPa, about 80 MPa, about 85 MPa, about 90 MPa, about 95 MPa, about 100 MPa, about 110 MPa, about 115 MPa, about 120 MPa, about 125 MPa, about 130 MPa, about 135 MPa, about 140 MPa, about 150 MPa, about 160 MPa, about 170 MPa, about 180 MPa, about 190 MPa, about 200 MPa, about 250 MPa, or about 300 MPa, or any value therebetween.

A printed circuit board (PCB) typically comprises an insulating layer between two films of a conductive cladding (e.g., copper cladding), though some applications use only one film of such conductive cladding. The conductive cladding layers are typically laminated to the insulating layer.

The composites 100, 200 described above, in any of their aspects or embodiments, can be used as the insulating layer or layers of a PCB to produce PCBs with good dielectric performance (e.g., low dielectric loss), dimensional stability at elevated temperature (e.g., at 260° C. for 30 seconds), sufficient mechanical strength to permit handling during production and post-processing (e.g., via drilling) without damage, burr, or fracture, good adhesion, and fire resistance.

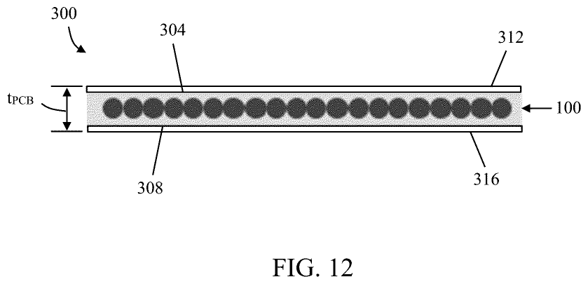

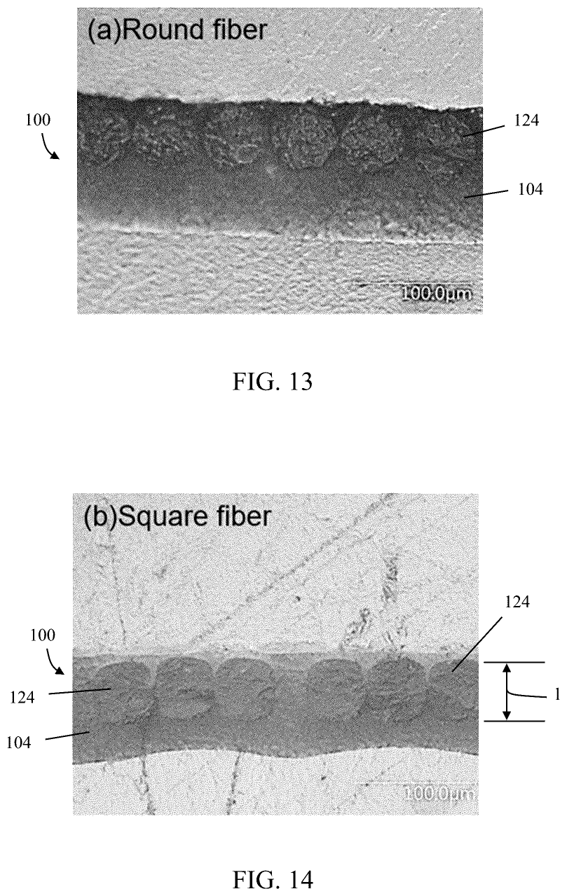

Referring now to FIG. 12, a printed circuit board (PCB) 300 according to embodiments of the present disclosure is shown. The PCB 300 comprises the composite 100 (or the composite 200) according to any embodiments disclosed herein. The composite 100 has a first side 304 and a second side 308 opposite the first side 304. The PCB 300 includes a first conductive layer 312 disposed on the first side 304 of the composite 100. In embodiments, the PCB 300 further includes a second conductive layer 316 disposed on the second side 308 of the composite 100.

In embodiments, the PCB 300 has a thickness t_{PCB} in a range of from about 35 μm to about 2.15 mm, or from about 40 μm to about 2.1 mm, or from about 45 μm to about 2.05 mm, or from about 50 μm to about 2 mm, or from about 55 μm to about 1.9 mm, or from about 60 μm to about 1.75 mm, or from about 65 μm to about 1.5 mm, and also comprising all sub-ranges and sub-values between these range endpoints.

### EXAMPLES

Various embodiments of the present disclosure can be better understood by reference to the following Examples which are offered by way of illustration. The present disclosure is not limited to the Examples given herein.

### Example 1—Forming Single Layer Composites

Sample composites having the configuration of the composite 100 (e.g., single composite or single-layer composite) were fabricated according to the methods described with respect to FIGS. 4-7. A length of uncoated continuous silica fiber was drawn as described above. The tractor and pulleys 168 were kept wet with ethyl alcohol as described above. The continuous silica fiber 124a was wound on top of the 30 μm thick sheet of Topas (e.g., the first polymer layer 104a) taped to the glass spool 160. The traverse pitch was set to the width of the fiber. With this traverse pitch, the continuous silica fiber 124a would be wound in a helix with one turn abutting the next turn such that there were no gaps between the turns. Enough continuous silica fiber 124a was drawn to cover the entire surface of Topas 104a on the spool (e.g., approximately 800 meters) so as to form the rolled continuous silica fiber 124b.

Next, another layer of 30 μm thick Topas (e.g., the second polymer layer 104b) was placed on the rolled continuous silica fiber 124b. Care was taken to place the second layer of Topas 104b on the rolled continuous silica fiber 124b so there were no wrinkles in the sheet. A piece of scotch or fiber glass tape was used to hold the Topas 104b to the spool 160.

Next, the spool 160 was placed in a vacuum oven. The vacuum oven was evacuated to 0.09 MPa. Then the vacuum oven was turned on and the following temperature program was followed: heat to a first temperature of approximately 197° C. over a ramp time of approximate 40 minutes; dwell at the first temperature for a dwell time of approximately 30 minutes; and cool to a second temperature less than the first temperature and greater than room temperature over a cool time of approximately 10 minutes. The sample was then removed from the vacuum oven and allowed to cool to room temperature. The laminated sheet was cut with a knife at the seam and taken off the spool.

Samples of the single-layer composites were fabricated from round silica fiber having a diameter of approximately 50 μm. Samples of the single-layer composites were also fabricated from square silica fiber having a side length of approximately 48 μm. FIG. 13 is an optical cross section image of a sample single-layer composite formed from the round silica fiber. FIG. 14 is an optical cross section image of a sample single-layer composite formed from the square silica fiber. As shown in FIG. 13 and FIG. 14, polymer layers 104 formed from Topas with 30 μm thickness were laminated on both side of the fiber. The volume ratio of the square fiber is approximately 4.26% higher than the round fiber in the composites. The absence of a clear interface between the Topas and fiber layer and the void free cross section indicate the good adhesion between Topas and the silica fiber achieved by the process. The fiber is well aligned inside the Topas and the pressurization did not cause the fiber to break.

### Example 2—Forming Double Layer Composites

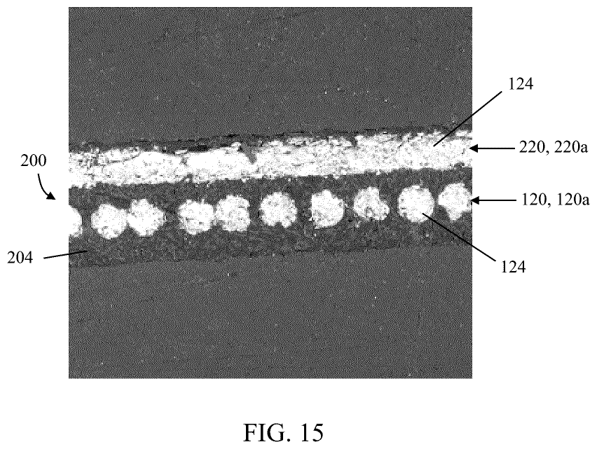

Sample composites having the configuration of the composite 200 (e.g., double composite or double-layer composite) were fabricated according to the methods described with respect to FIGS. 8-11. Samples of the double-layer composites 200 were fabricated by placing two, single-layer composites 100, each single-layer composite 100 measuring approximately 4 inch×4 inch square, one on top of the other in a stainless steel mold, oriented with approximately perpendicular fiber alignments (e.g., FIG. 8 and FIG. 9). Teflon and rubber silicon sheets were added to maintain flatness during lamination. The two, single-layer composites 100 were then bonded together under vacuum in a hot press. The press was a standard benchtop manual heated lab press, manufactured by Carver Inc. and equipped with a pressure gauge and temperature controllers. FIG. 15 is an SEM cross section of a sample double-layer composite formed according to the procedure described herein.

### Example 3—Dielectric Property Measurements

The permittivity (εᵣ′) and loss tangent (tanδ) of the composites were measured using a Split Post Dielectric Resonator (SPDR) (QWED Company, Poland). To measure the permittivity and loss tangent of a sample, the resonance frequency and Q-factor of the empty cavity (no sample inserted) were first measured. The resonance frequency of the cavity was about 15 GHZ, and the Q factor was about 8000. The measurements were then repeated with the sample in place. In general, the setup typically requires a sample width of 20-30 mm, and the thickness less than 0.6 mm. From these four resonance parameters (resonance frequency and Q factor for the cavity without and without the sample), and the thickness of the sample, (typically 0.1 mm to 0.2 mm), the permittivity and loss tangent were calculated using software provided by QWED. A convenient attribute of this procedure is that there were no additional resonances in the vicinity to interfere with the main resonance, so there was no ambiguity in the measurement. The measured samples typically shifted the resonance frequency downwards by on the order of 50 MHz and reduced the Q factor by about 1000. The measurements were made using a Keysight N5242A 26.5 GHz network analyzer. The permittivity and loss tangent values reported in Table 1 and Table 2 were averaged from three-to-five different areas of measurements per sample.

TABLE 1
Dielectric Properties for Single-Layer Composites

| Sample Number | Permittivity (εᵣ′) | Loss Tangent (tanδ) |
|---|---|---|
| 1-1 | 2.83 | 0.0013 |
| 1-2 | 3.01 | 0.0011 |
| 1-3 | 2.81 | 0.0013 |
| 1-4 | 2.70 | 0.0009 |
| 1-5 (square fiber) | 2.51 | 0.0008 |

Samples 1-1 through 1-4 were single-layer composites formed from continuous silica fibers having a round cross section whereas Sample 1-5 was a single-layer composite formed from continuous silica fibers having a square cross section. The samples had an average permittivity of 2.77±0.18 and an average loss tangent of 0.0011±0.0002.

TABLE 2
Dielectric Properties for Double-Layer Composites

| Sample Number | Permittivity (εᵣ′) | Loss Tangent (tanδ) |
|---|---|---|
| 2-1 | 3.07 | 0.0010 |
| 2-2 | 2.32 | 0.0008 |
| 2-3 | 3.19 | 0.0016 |

The samples had an average permittivity of 2.9±0.5. The samples had an average loss tangent of 0.0011±0.0004.

### Example 4—Mechanical Property Measurements

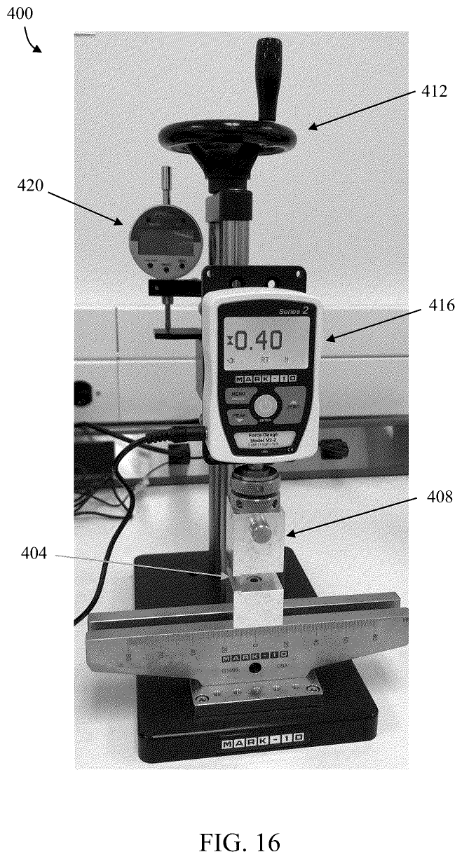

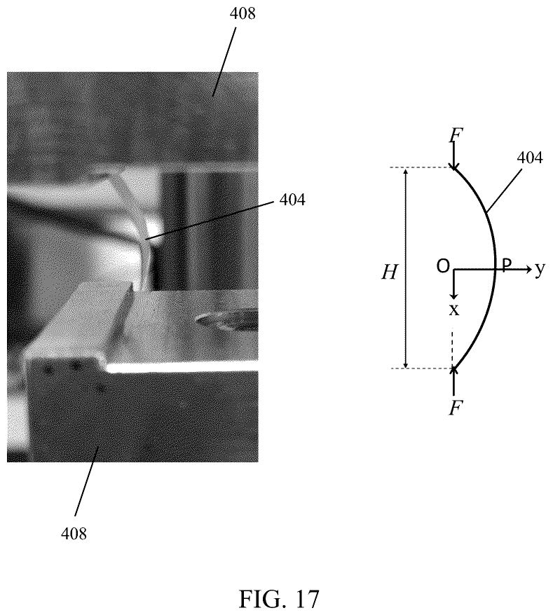

The flexural modulus and flexural strength of the sample composites were measured using a 2-point bend test performed with the test configuration 400 illustrated in FIG. 16 and described herein. The measurements were performed while each test sample 404 was held in a sample holder 408, as shown in FIG. 16 and FIG. 17. The compressive load applied (F) on the sample via rotation of a lead screw 412 was within a range of 0-10 N and measured using a Mark-10 M2-2 series 2 digital force gauge 416 The deflection of the sample was measured using a depth gauge 420 from Fowler High Precision Tools & Measuring Instruments. The flexural modulus (E) of a sample of width a, thickness b, and length l was measured using the following Euler buckling analysis described in the next paragraph. In short, the bent sample acts as a constant force spring (with force F) in the 2-point tester, and the force is essentially constant over a wide range of deflections.

As shown in FIG. 17, the sample 404 is held rotationally-free at each end. For small deflections, H (the separation between the ends of the sample) is approximately the length of the sample (L). R is its radius of curvature at its center, x=0. In the small deflection case,

$$\frac{1}{R} \approx {\vert \frac{{d}^{2} y}{{dx}^{2}} \vert}_{x = 0} ,$$

the shape of the sample is co-sinusoidal, and so its equation is

$$y = \frac{{L}^{2}}{{π}^{2} R} cos \frac{π x}{L}$$

under these particular boundary conditions. At the center of the sample (x=0), the bending moment exerted by the applied force is

$$M = F \frac{{L}^{2}}{{π}^{2} R} .$$

This is balanced by an internal bending moment

$$M = \frac{EI}{R}$$

where E is the flexural modulus of the sample, and I is the second moment of area of its cross section. Equating these two expressions for M gives the Euler buckling equation:

F_{buckling}=π²EI/L² (Equation 1)

or

E=F_{buckling}L²/π²I (Equation 1)

where I is the second moment of area of the cross section. For a sample of rectangular cross section, I=ab³/12 where a is the width and b is the thickness.

The same test configuration was used to measure flexural strength (σ_{f}). A short piece of the sample composite was bent until it fractured. The flexural strength (σ_{f}) was then calculated from the distance between the two ends of the sample at fracture (d) and the thickness of the sample (b). In addition, a correction factor for short samples was incorporated. This correction factor was derived as described in Matthewson, M. J. et al., “Strength Measurement of Optical Fibers by Bending,” Journal of the American Ceramic Society, Volume 69, 1986, pages 815-821, under conditions in which the tangential angle (ψ) between the sample and the faceplates is non-zero. The resulting equation for flexural strength is:

$${σ}_{f} = 1.2 \times \sqrt{cos ( ψ )} \times E \times \frac{b}{d - b} \qquad ( Equation 2 )$$

Samples of the single-layer composites and the double-layer composites were cut into small pieces measuring approximately 0.5 inches×0.5 inches and then tested for flexural modulus and flexural strength using the 2-point bend test described above. The load (F) in Newtons was measured as a function of deflection (δ mm) of the sample while bending, and flexural modulus and flexural strength were then calculated according to Equation 1 and Equation 2.

The mechanical properties are dependent on the loading direction corresponding to the fiber alignment. The goal of using fiber to make reinforced composites is to achieve the enhanced mechanical properties, e.g., higher strength, modulus, stiffness, etc. The mechanical properties of the fiber reinforced composite depend not only on the properties of the fiber and volume ratio, but also on the fiber length, orientation, and bond strength to the polymer matrix.

The composites fabricated in this work have continuous and oriented fiber inside the polymer matrix, and the reinforcement has the greatest effect in the longitudinal direction and the smallest effect in the transverse direction. Thus, the mechanical characteristics of the composites are dependent on the fiber orientation, and reinforcement efficiency reaches the maximum in the longitudinal direction of the fiber alignment and approaches zero in the transverse direction of the fiber alignment.

Measurements of flexural modulus in the longitudinal direction were made on four samples. The volume fraction for the silica was around 34.5%, and the average flexural modulus was 5.2±0.7 GPa. The flexural strength calculated from the 2-point bend test was in a range of from about 139 MPa to about 164 MPa.

While the disclosure has been illustrated and described in detail in the drawings and foregoing description, the same should be considered as illustrative and not restrictive in character. It is understood that only the preferred embodiments have been presented and that all changes, modifications and further applications that come within the spirit of the disclosure are desired to be protected.

What is claimed is:

1. A composite, comprising:
a polymer layer; and
a fiber layer encapsulated within the polymer layer, the fiber layer comprising a first monolayer of continuous silica fibers longitudinally co-aligned in a first direction, each continuous silica fiber in the first monolayer extending without discontinuity through the polymer layer such that opposed ends thereof are adjacent to a perimeter of the polymer layer,
wherein the composite has a dielectric loss tangent of less than or equal to about 0.0015 at 15 GHz or higher frequency.

2. The composite of claim 1, wherein the composite has a dielectric loss tangent of less than or equal to about 0.0005 at 15 GHz or higher frequency.

3. The composite of claim 1, wherein the composite has a dielectric constant of less than or equal to 5.

4. The composite of claim 1, wherein the composite has a flexural modulus of about 1 GPa to about 100 GPa or a flexural strength of about 20 MPa to about 175 MPa when measured in the first direction.

5. The composite of claim 1, wherein the continuous silica fibers are spaced uniformly in the first monolayer.

6. The composite of claim 1, wherein the continuous silica fibers are positioned in contact with one another in the first monolayer.

7. The composite of claim 1, wherein the fiber layer comprises a second monolayer of the continuous silica fibers longitudinally co-aligned in a second direction transverse to the first direction, the second monolayer having a planar offset relative to the first monolayer with each continuous silica fiber in the second monolayer extending without discontinuity through the polymer layer such that opposed ends thereof are adjacent to the perimeter of the polymer layer.

8. The composite of claim 7, wherein the second direction is transverse to the first direction by an angle in a range of from about 85° to about 95°.

9. The composite of claim 7, wherein the continuous silica fibers are spaced uniformly in the second monolayer.

10. The composite of claim 7, wherein the continuous silica fibers are positioned in contact with one another in the second monolayer.

11. The composite of claim 1, wherein the continuous silica fibers are high-purity continuous silica fibers.

12. The composite of claim 1, wherein the continuous silica fibers do not have a coating.

13. The composite of claim 1, wherein the continuous silica fibers have a round cross section.

14. The composite of claim 13, wherein a diameter of the continuous silica fibers is in a range of from greater than or equal to about 10 μm to less than or equal to about 1 mm.

15. The composite of claim 1, wherein the continuous silica fibers have a square cross section.

16. The composite of claim 15, wherein a length of one side of the square cross section is in a range of from greater than or equal to about 10 μm to less than or equal to about 1 mm.

17. The composite of claim 1, wherein the polymer layer has a thickness in a range of from about 20 μm to about 2 mm, and wherein the thickness of the polymer layer is greater than a thickness of the fiber layer.

18. The composite of claim 1, wherein the polymer layer comprises at least one polymer selected from cyclic olefin polymers or copolymers, polystyrene polymers (PS), polyetheretherketone polymers (PEEK), polyetherimide polymers (PEI), liquid crystal polymers, polypropylene polymers, cyclic olefins, linear olefins, bi-cyclic olefin norbornene and/or ethylene, polyisobutylene, 4-methylpentene, (dimethyl) polyphenyloxide (PPO), or combination thereof.

19. The composite of claim 1, wherein the polymer layer comprises a polymer composite material, the polymer composite material comprising a cyclic olefin copolymer and a fluoropolymer, wherein the cyclic olefin copolymer and the fluoropolymer are present in a ratio of between 1:99 and 99:1.

20. A method of forming a composite for a printed circuit board (PCB), comprising:
longitudinally co-aligning continuous silica fibers in a first monolayer on a first polymer layer;
covering the continuous silica fibers and the first polymer layer with a second polymer layer; and
encapsulating the continuous silica fibers within a unified polymer layer comprising the first polymer layer and the second polymer layer to form the composite,
wherein the composite has a dielectric loss tangent of less than or equal to about 0.0015 at 15 GHz or higher frequency.
